(19) United States
(12) Patent Application Publication
(10) Pub. No.: US 2025/0160513 A1
(43) Pub. Date: May 22, 2025

(54) HANGER ASSEMBLY

(71) Applicant: Vertiv Corporation, Westerville, OH (US)

(72) Inventors: ADARSH KHANDELWAL, Pune (IN); AKSHAY SHAH, Pune (IN)

(21) Appl. No.: 18/947,456

(22) Filed: Nov. 14, 2024

(30) Foreign Application Priority Data
Nov. 16, 2023 (IN) 202321077966

(51) Int. Cl. A47B 47/00; H05K 7/18

(52) U.S. Cl. CPC A47B 47/0066; H05K 7/18

(57) ABSTRACT

A hanger assembly includes a first panel having a proximate edge and a distal edge, each having at least one cut-out and at least one lance. The hanger assembly also includes a second panel having a proximate edge and a distal edge each having at least one cut-out and at least one lance. The hanger assembly is deformable such that the second panel abuts the first panel and each of lances of each of the first panel and the second panel are received by respective cut-outs of the first panel and the second panel.

### CROSS REFERENCE TO RELATED APPLICATIONS

This U.S. Non-Provisional Patent Application claims the benefit of Indian Provisional Patent Application Serial No. 202321077966 titled “A Hanger Assembly” filed Nov. 16, 2023, the entire disclosure of which is hereby incorporated by reference.

### FIELD

The present disclosure relates to a hanger assembly.

### BACKGROUND

Generally, in a traditional hanger assembly, various components are typically affixed to a sturdy surface or cabinet by means of fasteners. However, the use of fasteners lacks a convenient way to remove and reposition a traditional hanger assembly. Moreover, the conventional approach to repositioning a traditional hanger assembly is a time-consuming task, demanding the expertise of a trained technician. Consequently, if there is a need to temporarily reposition a hanger, a trained professional may be required to do so.

### SUMMARY

An aspect of the disclosed embodiments includes an apparatus. The apparatus includes a hanger assembly that includes a first panel having a proximate edge having at least one cut-out and at least one lance, and a distal edge having at least one cut-out and at least one lance. The hanger assembly also includes a second panel having a proximate edge having at least one cut-out and at least one lance, and a distal edge having at least one cut-out and at least one lance. The hanger assembly is deformable such that the second panel abuts the first panel, the at least one cut-out of the proximate edge of the first panel receives the at least one lance of the proximate edge of the second panel, the at least one cut-out of the distal edge of the first panel receives the at least one lance of the distal edge of the second panel, the at least one cut-out of the proximate edge of the second panel receives the at least one lance of the proximate edge of the first panel, and the at least one cut-out of the distal edge of the second panel receives the at least one lance of the distal edge of the first panel.

### BRIEF DESCRIPTION OF THE ACCOMPANYING DRAWING

A hanger assembly, of the present disclosure will now be described with the help of the accompanying drawing in which:

FIG. 1 illustrates a perspective view of an electrical cabinet with a hanger assembly in accordance with an embodiment of the present disclosure.

FIG. 2a illustrates an exploded view of the deformable hanger assembly in accordance with a first embodiment of the present disclosure, and FIG. 2b illustrates a perspective isometric view of the deformable hanger assembly in accordance with the first embodiment of the present disclosure.

FIG. 3a illustrates an exploded view of the hanger assembly in accordance with a second embodiment of the present disclosure.

FIG. 3b illustrates the mounting configuration of the first panel and the second panel as an embodiment of the present disclosure.

### DETAILED DESCRIPTION

Embodiments, of the present disclosure, will now be described with reference to the accompanying drawing.

Embodiments are provided so as to thoroughly and fully convey the scope of the present disclosure to the person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, elements, modules, units and/or components, but do not forbid the presence or addition of one or more other features, elements, components, and/or groups thereof.

Typically, in a traditional hanger assembly, various components are typically affixed to a sturdy surface or cabinet by means of fasteners. However, the use of fasteners lacks a convenient way to remove and repositioning of the traditional hanger assembly. Moreover, the conventional approach to repositioning a traditional hanger assembly proves to be a time-consuming task, demanding the expertise of a trained technician. Consequently, if there is a need to temporarily reposition, a trained professional may be required.

Accordingly, systems and methods, such as those described herein, configured to provide an improved hanger assembly, may be desirable. In some embodiments, the systems and methods described herein may be configured to provide a hanger assembly. The systems and methods described herein may be configured to provide a hanger assembly that can be secured to any surface without using fasteners. The systems and methods described herein may be configured to provide a hanger assembly that can be easily repositioned based on the user requirements. The systems and methods described herein may be configured to provide a hanger assembly that can be easily removed and reinstalled during maintenance without requiring complete removal of the assembly from the cabinet.

The systems and methods described herein may be configured to provide a hanger assembly that can reduce the time required for repositioning, maintenance, and/or adjustments, leading to increased operational efficiency. The systems and methods described herein may be configured to provide a hanger assembly that can be a user-friendly configuration and does not require skilled man power to perform repositioning and/or maintenance. The systems and methods described herein may be configured to provide a hanger assembly that can minimize the risk of an accident during repositioning, adjustment or maintenance.

The systems and methods described herein may be configured to provide a hanger assembly that has a modular configuration. The systems and methods described herein may be configured to provide a hanger assembly that can be cost-effective in terms of initial setup and maintenance, minimizing the overall expenses during use. The systems and methods described herein may be configured to provide a hanger assembly that can be integrated into existing cabinets without significant modifications or retrofitting. The systems and methods described herein may be configured to provide a hanger assembly that has a removable panel and offers ease of assembly.

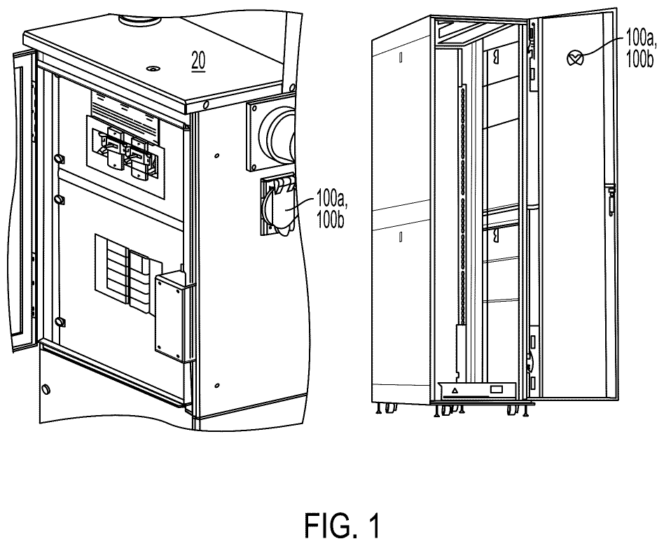

As is generally illustrated in FIGS. 1-3, a hanger assembly (100) (herein after referred as assembly (100)) for hanging or supporting an object thereon may be attached or mounted to any rigid surface or a side panel or a door panel of the cabinet (20). The hanger assembly (100) can be used to facilitate mounting between any two sheet-metal based components.

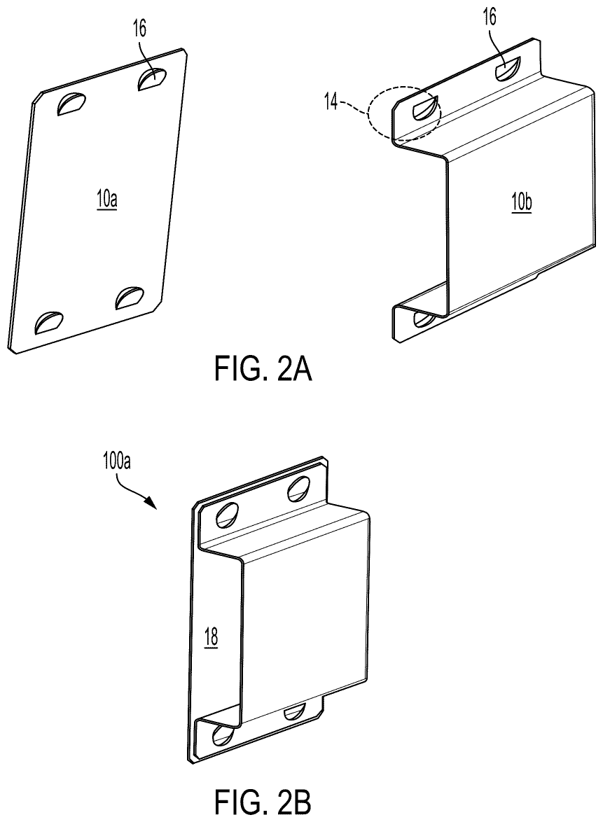

In accordance with an embodiment of the present disclosure, the hanger assembly (100) may include a first panel (10a) and a second panel (10b), as shown in FIG. 2a. The first panel (10a) may be defined by a flat metal sheet with a front surface and a rear surface. Each extreme portion (e.g., proximate and distal edge) of the first panel (10a) may be configured with at least a pair of first cut-outs (12a) with a lance (16) therein. In some embodiments, the lance (16) can define a tab (e.g., formed by the partial cut-out of the first panel (10a)). The lance (16) may be operatively bent and raised at a desired angle on the front surface of the first panel (10a) to define the first cut-out (12a) therein. Similarly, each extreme portion of the second panel (10b) may be configured with at least a pair of second cut-outs (12b) with the lance (16) (e.g., tab) therein.

In some embodiments, the hanger assembly may be deformable or collapsible such that the second panel (10b) abuts the first panel (10a) and the respective lance (16) correspondingly provided on the second panel (10b) and the first panel (10a) are allowed to be received within the first cut-out (12a) and the second cut-out (12b), respectively, and may be configured to interlock with each other to define a deformable hanger assembly (100).

In some embodiments, the second panel (10b) may be shaped as a U-shaped panel with a pair of extreme portions, extending from the edge of the U-shaped panel. In some embodiments, the second panel (10b) may be configured to slidably interlock with the operative portion of the first panel (10a) to form an enclosure (18) or cavity to hold and support a desired object therein.

In some embodiments, the corresponding lance (16) provided on the first panel (10a) and the second panel (10b) may be aligned in the same direction. FIG. 2a illustrates an exploded view of a hanger assembly (100) in accordance with some embodiments, and FIG. 2b illustrates a perspective isometric view of the hanger assembly (100) in accordance with another embodiment.

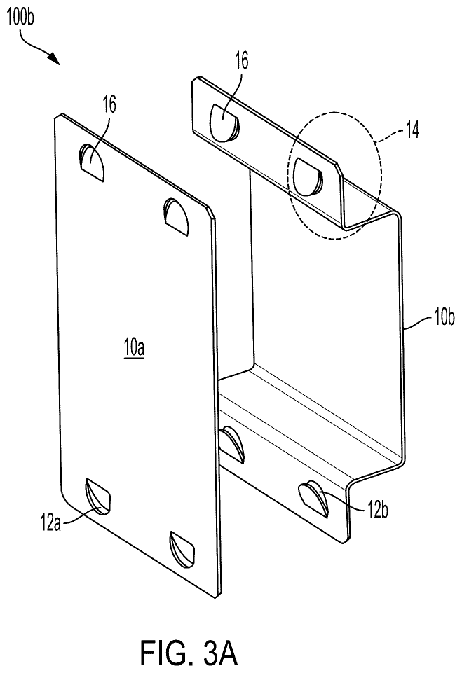

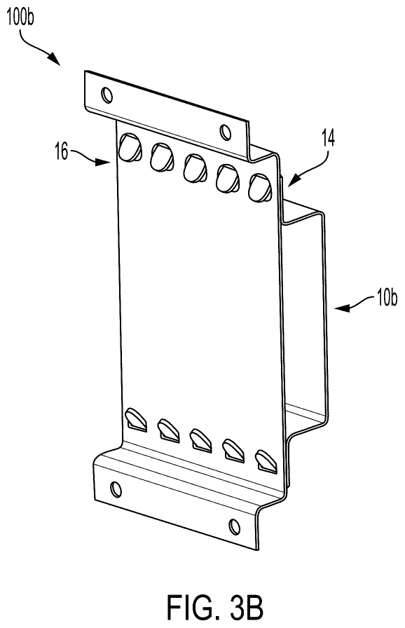

In some embodiments, the lance (16) provided on the first panel (10a) and the second panel (10b) may be aligned in the opposite direction. FIG. 3a illustrates an exploded view of the hanger assembly (100) in accordance with another embodiment of the present disclosure.

In some embodiments of the assembly (100), when the second panel (10b) interlock with the operative portion of the first portion, the lance (16) provided on the operative portion of the second panel (10b) and the first panel (10a) may be configured to slide within the respective cut-outs, to thereby lance (16) interlock and forms a hook-loop configuration. The hook-loop configuration of the hanger assembly (100) offers self-locking and thus, ease of assembly-disassembly without requirement of any external hardware or fasteners.

In some embodiments, the hanger assembly (100) may be mounted or affixed to any surface of the cabinet (20) or wardrobe surface by means of an adhesive tape. The rear surface of the first panel (10a) may be affixed to any required surface by means of the adhesive tape and then the second panel (10b) may be fitted to form the hanger assembly (100).

In some embodiments, the first panel (10a) and the second panel (10b) may be selected from a group of materials consisting of metal sheets, alloy sheets, polymeric material sheets with a desired strength and thermal conductivity property.

In some embodiments, the first panel (10a) may be mounted to a rigid surface by means of fasteners and the lance (16) provided on the second panel (10b) maybe snap fitted to the cut-out provided within the first panel (12a), such as shown in FIG. 3b.

The foregoing description of the embodiments has been provided for purposes of illustration and not intended to limit the scope of the present disclosure. Individual components of a particular embodiment are generally not limited to that particular embodiment, but, are interchangeable. Such variations are not to be regarded as a departure from the present disclosure, and all such modifications are considered to be within the scope of the present disclosure.

In some embodiments, the systems and methods described herein may be configured to provide a hanger assembly that: can be secured to any surface without using fasteners; can be easily repositioned based on the user requirements; can be easily removed and reinstalled during maintenance without requiring complete removal of the assembly from the cabinet; can reduce the time required for repositioning, maintenance, and adjustments, leading to increased operational efficiency; can be a user-friendly configuration and does not require skilled man power to perform repositioning, or maintenance; can minimize the risk of accidents during repositioning, adjustment or maintenance; has a modular configuration; can be cost-effective in terms of initial setup and maintenance, minimizing the overall expenses during use; can be integrated into existing cabinets without significant modifications or retrofitting; and/or has a removable panel and offers ease of assembly.

The foregoing disclosure has been described with reference to the accompanying embodiments which do not limit the scope and ambit of the disclosure. The description provided is purely by way of example and illustration.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Any discussion of devices, articles or the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

1. An apparatus comprising:
a hanger assembly that includes:
a first panel having:
a proximate edge having at least one cut-out and at least one lance; and
a distal edge having at least one cut-out and at least one lance; and
a second panel having:
a proximate edge having at least one cut-out and at least one lance; and
a distal edge having at least one cut-out and at least one lance,
wherein:
the hanger assembly is deformable such that the second panel abuts the first panel;
the at least one cut-out of the proximate edge of the first panel receives the at least one lance of the proximate edge of the second panel;
the at least one cut-out of the distal edge of the first panel receives the at least one lance of the distal edge of the second panel;
the at least one cut-out of the proximate edge of the second panel receives the at least one lance of the proximate edge of the first panel; and
the at least one cut-out of the distal edge of the second panel receives the at least one lance of the distal edge of the first panel.

2. The apparatus of claim 1, wherein the first panel is defined by a flat sheet.

3. The apparatus of claim 1, wherein the at least one lance of the proximate edge of the first panel is bent and raised relative to a surface of the first panel.

4. The apparatus of claim 1, wherein the at least one lance of the distal edge of the first panel is bent and raised relative to a surface of the first panel.

5. The apparatus of claim 1, wherein the at least one lance of the proximate edge of the second panel is bent and raised relative to a surface of the second panel.

6. The apparatus of claim 1, wherein the at least one lance of the distal edge of the second panel is bent and raised relative to a surface of the second panel.

7. The apparatus of claim 1, wherein the second panel comprises a U-shaped portion.

8. The apparatus of claim 7, wherein the proximate edge of the second panel extends in a first direction from the U-shaped portion.

9. The apparatus of claim 8, wherein the distal edge of the second panel extends in a second direction, opposite the first direction, from the U-shaped portion.

10. The apparatus of claim 1, wherein the second panel is configured to slidably interlock with a portion of the first panel to form an enclosure.

11. The apparatus of claim 1, wherein the at least one lance of the proximate edge of the first panel may be aligned in a same direction as the at least one lance of the proximate edge of the second panel.

12. The apparatus of claim 1, wherein the at least one lance of the distal edge of the first panel may be aligned in a same direction as the at least one lance of the distal edge of the second panel.

13. The apparatus of claim 1, wherein the at least one lance of the proximate edge of the first panel may be aligned in an opposite direction as the at least one lance of the proximate edge of the second panel.

14. The apparatus of claim 1, wherein the at least one lance of the distal edge of the first panel may be aligned in an opposite direction as the at least one lance of the distal edge of the second panel.

15. The apparatus of claim 1, wherein a first surface of the first panel is affixed to a rigid surface.

16. The apparatus of claim 15, wherein the rigid surface corresponds to a cabinet.

17. The apparatus of claim 1, wherein the first panel comprises at least one of a metal material, an allow material, a polymeric material.

18. The apparatus of claim 1, wherein the second panel comprises at least one of a metal material, an allow material, a polymeric material.

19. The apparatus of claim 1, wherein the at least one lance of the proximate edge of the first panel is formed by a partial cut-out of the first panel, and wherein the at least one lance of the distal edge of the first panel is formed by a partial cut-out of the first panel.

20. The apparatus of claim 1, wherein the at least one lance of the proximate edge of the second panel is formed by a partial cut-out of the second panel, and wherein the at least one lance of the distal edge of the second panel is formed by a partial cut-out of the second panel.
